(19) United States
(12) Patent Application Publication
(10) Pub. No.: US 2010/0090246 A1
(43) Pub. Date: Apr. 15, 2010

(54) VERTICAL NITRIDE-BASED LIGHT EMITTING DIODE AND METHOD OF MANUFACTURING THE SAME

(75) Inventors: Jin Bock LEE, Gyeonggi-do (KR); Jin Hyun Lee, Gyeonggi-do (KR); Hee Seok Park, Gyeonggi-do (KR); Pun Jae Choi, Gyeonggi-do (KR); Jong In Yang, Gyeonggi-do (KR)

Correspondence Address: MCDERMOTT WILL & EMERY LLP, 600 13TH STREET, N.W., WASHINGTON, DC, 20005-3096, US

(73) Assignee: SAMSUNG ELECTRO-MECHANICS CO. LTD.

(21) Appl. No.: 12/328,142

(22) Filed: Dec. 4, 2008

(30) Foreign Application Priority Data
Oct. 9, 2008 (KR) 10-2008-0098917

(51) Int. Cl. H01L 33/00; H01L 21/18

(52) U.S. Cl. 257/103; 438/22; 257/E33.023; 257/E21.085

(57) ABSTRACT

Provided is a vertical nitride-based LED including a first electrode; a first nitride semiconductor layer that is disposed on the first electrode; an active layer that is disposed on the first nitride semiconductor layer; a second nitride semiconductor layer that is disposed on the active layer; an ohmic contact pattern that is disposed on the second nitride semiconductor layer; a second electrode that is disposed on the ohmic contact pattern; and a bonding pad that is electrically connected to the second electrode and disposed on the second nitride semiconductor layer.

### CROSS-REFERENCE TO RELATED APPLICATIONS

This application claims the benefit of Korean Patent Application No. 10-2008-0098917 filed with the Korea Intellectual Property Office on Oct. 9, 2008, the disclosure of which is incorporated herein by reference.

### BACKGROUND OF THE INVENTION

1. Field of the Invention

The present invention relates to a vertical nitride-based light emitting diode (LED) and a method of manufacturing the same.

2. Description of the Related Art

LEDs which emit light through recombination of electrons and holes are used as light sources of electronic products. In particular, LEDs are widely used in small-sized portable products such as mobile phone keypads and camera flashlights.

An LED includes a pair of electrodes and a light emission structure. The LED may be divided into horizontal and vertical structures, depending on the disposition structure of the electrodes and the light emission structure.

In the vertical LED, a light emission structure is disposed so as to be interposed between a pair of electrodes, that is, a negative (n-) electrode and a positive (p-) electrode such that the respective components are vertically stacked. In this case, the n-electrode includes a bonding pad which is electrically connected to an external device so as to receive power.

In the vertical LED, currents flow in the vertical direction. Therefore, the current spreading efficiency of the vertical LED is higher than the horizontal LED. Further, the vertical LED has higher current efficiency and light emission efficiency than the horizontal LED, and has a lower caloric value than the horizontal LED. Accordingly, the vertical LED can be effectively used as a light source applied to a backlight of large-sized electronic products, for example, large-sized TVs, a headlight of vehicle, a general lighting, and so on, which requires high power, high efficiency, and high reliability.

In the vertical LED, however, since currents flow in the vertical direction, a current crowding effect may occur, in which the currents crowd into a lower portion of the bonding pad coming in contact with the external device. Due to the current crowding effect, light emitted from the light emission structure is concentrated in the lower portion of the bonding pad. Therefore, the overall light emission efficiency of the vertical LED decreases, thereby degrading the luminance of the vertical LED.

Therefore, the vertical LED can be used for large-sized electronic products, but the luminance of the vertical LED decreases due to the current crowding effect.

### SUMMARY OF THE INVENTION

An advantage of the present invention is that it provides a vertical nitride-based semiconductor LED which includes a second nitride semiconductor layer and a second electrode forming an ohmic contact and a second nitride semiconductor layer and a bonding pad forming a Schottky contact, thereby minimizing a current crowing effect.

Another advantage of the present invention is that it provides a method of manufacturing a vertical nitride-based LED.

Additional aspect and advantages of the present general inventive concept will be set forth in part in the description which follows and, in part, will be obvious from the description, or may be learned by practice of the general inventive concept.

According to an aspect of the invention, a vertical nitride-based LED comprises a first electrode; a first nitride semiconductor layer that is disposed on the first electrode; an active layer that is disposed on the first nitride semiconductor layer; a second nitride semiconductor layer that is disposed on the active layer; an ohmic contact pattern that is disposed on the second nitride semiconductor layer; a second electrode that is disposed on the ohmic contact pattern; and a bonding pad that is electrically connected to the second electrode and disposed on the second nitride semiconductor layer.

The bonding pad and the second nitride semiconductor layer may form a Schottky contact.

The bonding pad may include a first bonding pad which is disposed on the second nitride semiconductor layer and extends from the second electrode, and a second bonding pad disposed on the first bonding pad.

The bonding pad and the second electrode may be formed integrally.

The first electrode may be a p-electrode, and the second electrode may be an n-electrode.

The first and second nitride semiconductor layers may include GaN-based semiconductor.

According to another aspect of the invention, a method of manufacturing a vertical nitride-based LED comprises sequentially forming a second nitride semiconductor layer, an active layer, and a first nitride semiconductor layer on a substrate; forming a first electrode on the first nitride semiconductor layer; exposing the second nitride semiconductor layer by removing the substrate; forming an ohmic contact pattern on the second nitride semiconductor layer; and forming a second electrode disposed on the ohmic contact pattern and a bonding pad which is electrically connected to the second electrode so as to be disposed on the second nitride semiconductor layer.

The ohmic contact pattern may be formed by performing a surface treatment on the second nitride semiconductor layer.

The surface treatment may include providing a mask on the second nitride semiconductor layer, the mask having an opening corresponding to the second electrode; and irradiating laser onto the second nitride semiconductor layer including the mask.

The surface treatment may include selectively irradiating laser on the second nitride semiconductor layer.

The method may further comprise performing a cleaning process after the forming of the ohmic contact pattern.

The method may further comprise performing an annealing process after the forming of the ohmic contact pattern.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional view of a vertical nitride-based LED according to an embodiment of the invention;

FIGS. 2 to 5 are process diagrams for explaining a method of manufacturing a vertical nitride-based semiconductor LED according to a second embodiment of the invention;

FIG. 6 is a graph showing a contact characteristic between metal and a nitride semiconductor layer which is not subjected to a laser treatment; and

FIG. 7 is a graph showing a contact characteristic between metal and a nitride semiconductor layer which is subjected to a laser treatment.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to like elements throughout. The embodiments are described below in order to explain the present general inventive concept by referring to the figures. In the drawings, the thicknesses of layers and regions are exaggerated for clarity. Throughout the specification, like reference numerals represent the same components.

FIG. 1 is a cross-sectional view of a vertical nitride-based LED according to an embodiment of the invention.

Referring to FIG. 1, a first nitride semiconductor layer 110 is disposed on a first electrode 100.

The first electrode 100 serves to provide an electric charge to an active layer 120 which will be described below. For example, the first electrode 100 may be a p-electrode which provides holes to the active layer 120. The first electrode 100 may be formed of metal. For example, the first electrode 100 may have a single-layer or multi-layer structure including at least any one of Pd, Ni, Au, Ag, Cu, Pt, Co, Rh, Ir, Ru, Mo, and W.

Although not shown in FIG. 1, a conductive adhesive layer and a structure support layer may be disposed under the first electrode 100. The conductive adhesive layer serves to enhance contact stability between the first electrode 100 and the structure support layer. The conductive adhesive layer may be formed of any one of Au—Sn, Sn, In, Au—Ag, and Pb—Sn. Further, the structure support layer may serve as an electrode as well as a support layer for supporting the LED. The structure support layer may be formed of silicon or metal in consideration of thermal stability of the LED.

The first nitride semiconductor layer 110 may be formed of a semiconductor material doped with p-type impurities. The semiconductor material may be a Ga-based nitride semiconductor. For example, the Ga-based nitride semiconductor material may be GaN, AlGaN, GaInN or the like. Further, Mg, Zn, and Be may be taken as examples of the p-type impurities.

The active layer 120 is disposed on the first nitride semiconductor layer 110. The active layer 120 is a layer which emits light through recombination of electrons and holes provided by the first electrode 100 and a second electrode 200, respectively, which will be described below. The first nitride semiconductor layer 110 may be formed of GaN or InGaN having a single- or multi-quantum well structure.

A second nitride semiconductor layer 130 is disposed on the active layer 120. The second nitride semiconductor layer 130 may be formed of a semiconductor material doped with n-type impurities. The semiconductor material may be a Ga-based nitride semiconductor material. For example, the Ga-based nitride semiconductor material may be GaN, AlGaN, GaInN, or the like. Further, Si, Ge, Se, Te, and C may be taken as examples of the n-type impurities.

An ohmic contact pattern 140 is disposed on the second nitride semiconductor layer 130. The ohmic contact pattern 140 is formed by surface-treating the second nitride semiconductor layer 130, that is, irradiating laser onto the surface of the second nitride semiconductor layer 130.

The second electrode 150 is disposed on the ohmic contact pattern 140. The second electrode has a shape corresponding to that of the ohmic contact pattern 140. In this case, the second nitride semiconductor layer 130 and the second electrode 150 form an ohmic contact through the ohmic contact pattern 140.

The second electrode 150 may be formed of metal. For example, the second electrode 150 may be formed of any one of Ti, Cr, Al, Cu, and Au.

A bonding pad 160 which is electrically connected to the second electrode 150 is disposed on the second nitride semiconductor layer 130. The bonding pad 160 is electrically connected to an external element (not shown) so as to receive an electrical signal. The bonding pad 160 may be electrically connected to the external element through wire bonding or flip-chip bonding.

The second nitride semiconductor layer 130 and the bonding pad 160 form a Schottky contact. That is, while the second nitride semiconductor layer 130 and the second electrode 150 form an ohmic contact, the second nitride semiconductor layer 130 and the bonding pad 160 form a Schottky contact. Accordingly, contact resistance between the second nitride semiconductor layer 130 and the bonding pad 160 becomes higher than contact resistance between the second nitride semiconductor layer 130 and the second electrode 150. Therefore, electric currents applied from the bonding pad 160 do not crowd into the lower portion of the bonding pad 160, but spread into the lower portions of the bonding pad 160 and the second electrode 150.

The bonding pad 160 may include first and second bonding pads 160a and 160b. The first bonding pad 160a extends from the second electrode 150 so as to be disposed on the second nitride semiconductor layer 130. That is, the first bonding pad 160a and the second electrode 150 may be integrally formed. The second bonding pad 160b is disposed on the first bonding pad 160a.

In this embodiment of the invention, it has been described that the bonding pad 160 is formed of a double layer including the first and second bonding pads 160a and 160b. Without being limited thereto, however, the bonding pad 160 and the second electrode 150 may be integrally formed. That is, the second electrode 150 may extend so as to form the bonding pad 160.

In the vertical nitride-based LED according to the embodiment of the invention, since the second nitride semiconductor layer and the second electrode form an ohmic contact and the second nitride semiconductor layer and the bonding pad form a Schottky contact, electric currents can be prevented from crowding into the lower portion of the bonding pad. Therefore, it is possible to increase the luminance of the vertical nitride-based LED.

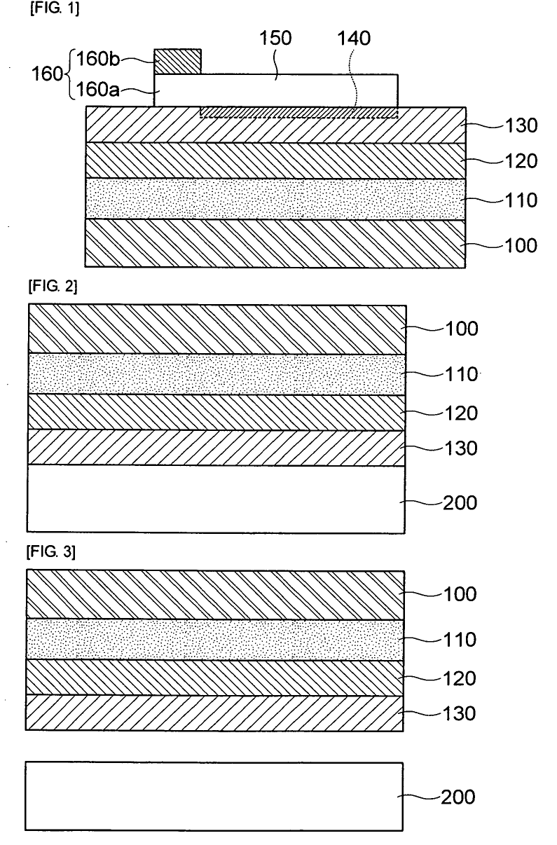

FIGS. 2 to 5 are process diagrams for explaining a method of manufacturing a vertical nitride-based semiconductor LED according to another embodiment of the invention.

First, as shown in FIG. 2, a substrate 200 is provided. The substrate 200 may be formed of a sapphire substrate.

The second nitride semiconductor layer 130, the active layer 120, and the first nitride semiconductor layer 110 may be sequentially grown and formed on the substrate 200. The second nitride semiconductor layer 130, the active layer 120, and the first nitride semiconductor layer 110 may be formed by metal-organic vapor deposition, molecular beam epitaxy (MBE), or hybrid vapor deposition.

The second nitride semiconductor layer 130 may be formed of a Ga-based nitride semiconductor material doped with n-type impurities. For example, the Ga-based nitride semiconductor material may be GaN, AlGaN, GaInN, or the like. Further, Si, Ge, Se, Te, and C may be taken as examples of the n-type impurities. The active layer 120 may be formed of GaN or InGaN having a multi-quantum well structure. The first nitride semiconductor layer 110 may be formed of a Ga-based semiconductor material doped with p-type impurities. For example, the Ga-based nitride semiconductor material may be GaN, AlGaN, GaInN or the like. Further, Mg, Zn, and Be may be taken as an example of the p-type impurities.

Thereafter, the first electrode 100 is formed on the first nitride semiconductor layer 110. The first electrode 100 may be formed by a vacuum deposition method or sputtering method. The first electrode 100 may be formed of any one of Pd, Ni, Au, Ag, Cu, Pt, Co, Rh, Ir, Ru, Mo, and W. The first electrode 100 may have a single-layer or multi-layer structure.

Although not shown, a structure support layer may be formed on the first electrode 100 through a conductive adhesive layer. The structure support layer may be a metal substrate or silicon substrate. Alternatively, without a separate conductive adhesive layer, the structure support layer may be directly formed on the first electrode 100 through any one of a deposition method, a sputtering method, and a plating method.

Referring to FIG. 3, the substrate 200 is removed so as to expose the second nitride semiconductor layer 130. The removing of the substrate 200 may be performed by a typical laser lift-off (LLO) process.

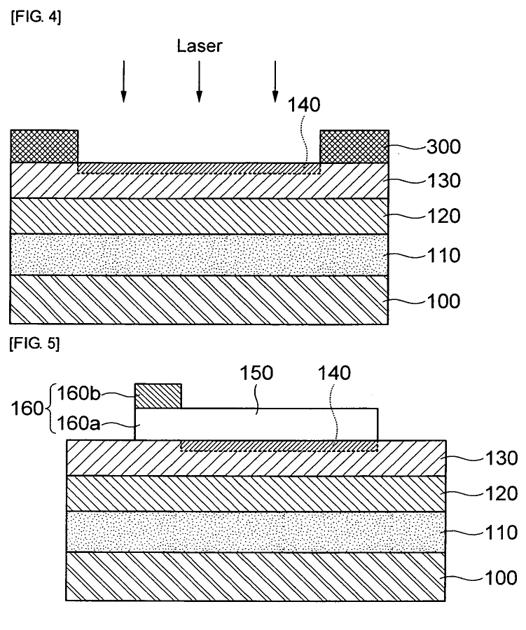

Referring to FIG. 4, a surface treatment is performed on a portion of the second nitride semiconductor layer 130, thereby forming an ohmic contact pattern 140. The surface treatment may be performed by irradiating laser.

Specifically, a mask 300 is provided on the second nitride semiconductor layer 130. The mask 300 includes an opening through which laser can pass and a cut-off portion which is disposed around the opening so as to cut off the laser.

Then, laser is irradiated on the mask 300. The laser passes through the opening of the mask 300 so as to be irradiated onto a portion of the second nitride semiconductor layer 130 corresponding to the opening, thereby forming the ohmic contact pattern 140. The laser may be excimer laser.

Specifically, the laser irradiation diffuses nitrogen (N) from the second nitride semiconductor layer 130 to the outside such that a plurality of N vacancies are formed on the surface of the second nitride semiconductor layer 130. That is, the ohmic contact pattern 140 including the plurality of N vacancies capable of reducing contact resistance to metal is formed on the surface of the second nitride semiconductor layer 130 by the laser irradiation.

In this embodiment of the invention, it has been described that the mask 300 is used for limiting a region onto which the laser is irradiated. However, without the mask 300, the laser may be selectively irradiated so as to form the ohmic contact pattern 140. This can be performed by inputting a laser irradiation region to a laser irradiation device.

After the laser irradiation process is completed, an annealing process and a cleaning process may be further performed.

The annealing process is a heat treatment process. Through the annealing process, an ohmic behavior can be improved, and the reliability of the LED can be secured.

Through the cleaning process, contaminants disposed on the surfaces of the ohmic contact pattern 140 and the second nitride semiconductor 130, and impurities generated during the laser irradiation process, for example, gallium oxide can be removed. The cleaning process may be performed using hydrochloric acid.

Referring to FIG. 5, the second electrode 150 and the first bonding pad 160a are formed on the second nitride semiconductor layer 130 including the ohmic contact pattern 140. The second electrode 150 and the first bonding pad 160a may be integrally formed. At this time, the second electrode 150 is disposed on the ohmic contact pattern 140, and the first bonding pad 160a is disposed on the second nitride semiconductor layer 130. The second electrode 150 and the first bonding pad 160a may be formed through a deposition method or sputtering method.

Thereafter, the second bonding pad 160b is formed on the first bonding pad 160a, thereby forming the bonding pad 160. At this time, the bonding pad 160 may be formed to have a double-layer structure including the first and second bonding pads 160a and 160b. Without being limited thereon, however, the bonding pad may have a single-layer structure integrated with the second electrode. That is, the bonding pad may be simultaneously formed during the process of forming the second electrode.

In this embodiment of the invention, the laser irradiation process is performed in such a manner that the second electrode and the second nitride semiconductor layer form an ohmic contact and the bonding pad and the second nitride semiconductor layer form a Schottky contact. Therefore, it is possible to minimize a current crowding effect in the lower portion of the bonding pad.

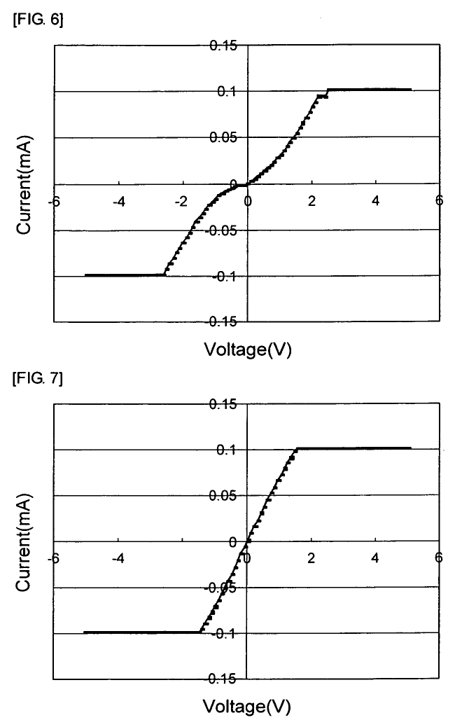

Hereinafter, a change in contact characteristic between a nitride semiconductor layer and metal depending on whether a laser treatment is performed or not will be described with reference to FIGS. 6 and 7.

FIG. 6 is a graph showing a contact characteristic between metal and a nitride semiconductor layer which is not subjected to a laser treatment.

As shown in FIG. 6, it can be found that the contact characteristic between the metal and the nitride semiconductor layer (that is, GaN) which is not subjected to a laser treatment shows a Schottky behavior.

FIG. 7 is a graph showing a contact characteristic between metal and a nitride semiconductor layer which is subjected to a laser treatment.

As shown in FIG. 7, it can be found that the contact characteristic between the metal and the nitride semiconductor layer (that is, GaN) which is subjected to a laser treatment shows an ohmic behavior.

Through the laser treatment, the interface contact resistance between the nitride semiconductor layer and the metal can be controlled.

In the method of manufacturing a vertical nitride-based LED according to the invention, as the laser treatment is selectively performed, currents do not crowd into the lower portion of the bonding pad, but spread inside the LED, thereby minimizing a current crowing effect. Therefore, it is possible to enhance the luminance of the vertical nitride-based LED.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A vertical nitride-based light emitting diode (LED) comprising:
a first electrode;
a first nitride semiconductor layer that is disposed on the first electrode;
an active layer that is disposed on the first nitride semiconductor layer;
a second nitride semiconductor layer that is disposed on the active layer;
an ohmic contact pattern that is disposed on the second nitride semiconductor layer;
a second electrode that is disposed on the ohmic contact pattern; and
a bonding pad that is electrically connected to the second electrode and disposed on the second nitride semiconductor layer.

2. The vertical nitride-based LED according to claim 1, wherein the bonding pad and the second nitride semiconductor layer form a Schottky contact.

3. The vertical nitride-based LED according to claim 1, wherein the bonding pad includes a first bonding pad which is disposed on the second nitride semiconductor layer and extends from the second electrode, and a second bonding pad disposed on the first bonding pad.

4. The vertical nitride-based LED according to claim 1, wherein the bonding pad and the second electrode are formed integrally.

5. The vertical nitride-based LED according to claim 1, wherein the first electrode is a p-electrode, and the second electrode is an n-electrode.

6. The vertical nitride-based LED according to claim 1, wherein the first and second nitride semiconductor layers include GaN-based semiconductor.

7. A method of manufacturing a vertical nitride-based LED, comprising:
sequentially forming a second nitride semiconductor layer, an active layer, and a first nitride semiconductor layer on a substrate;
forming a first electrode on the first nitride semiconductor layer;
exposing the second nitride semiconductor layer by removing the substrate;
forming an ohmic contact pattern on the second nitride semiconductor layer; and
forming a second electrode disposed on the ohmic contact pattern and a bonding pad which is electrically connected to the second electrode so as to be disposed on the second nitride semiconductor layer.

8. The method according to claim 7, wherein the ohmic contact pattern is formed by performing a surface treatment on the second nitride semiconductor layer.

9. The method according to claim 8, wherein the surface treatment includes:
providing a mask on the second nitride semiconductor layer, the mask having an opening corresponding to the second electrode; and
irradiating laser onto the second nitride semiconductor layer including the mask.

10. The method according to claim 8, wherein the surface treatment includes selectively irradiating laser on the second nitride semiconductor layer.

11. The method according to claim 7 further comprising:
performing a cleaning process after the forming of the ohmic contact pattern.

12. The method according to claim 7 further comprising:
performing an annealing process after the forming of the ohmic contact pattern.
